(19) United States
(12) Patent Application Publication
(10) Pub. No.: US 2013/0134299 A1
(43) Pub. Date: May 30, 2013

(54) DETECTOR FOR DETECTING ELECTROMAGNETIC RADIATION WITH TRANSFER GATE AND DRAINING GATE

(71) Applicants: Daniel DURINI ROMERO, Koeln (DE); Werner BROCKHERDE, Duisberg (DE); Bedrich HOSTICKA, Muelheim a.d.Ruhr (DE)

(72) Inventors: Daniel DURINI ROMERO, Koeln (DE); Werner BROCKHERDE, Duisberg (DE); Bedrich HOSTICKA, Muelheim a.d.Ruhr (DE)

(73) Assignee: Fraunhofer-Gesellschaft zur Foerderung der angewandten Forschung e.V., Munich (DE)

(21) Appl. No.: 13/479,322

(22) Filed: May 24, 2012

(30) Foreign Application Priority Data
May 27, 2011 (DE) 102011076635.9

(51) Int. Cl. H01L 27/148; H01L 31/09

(52) U.S. Cl. CPC H01L 27/148; H01L 31/09
USPC 250/216; 257/222; 438/60

(57) ABSTRACT

An electromagnetic radiation detector includes a semiconductor substrate of a first doping type, a well in the semiconductor substrate of a second doping type, two or more detector terminal doping regions, two or more transfer gates, and a collection gate. The first and second doping type are different and the well includes a rising dopant concentration in a direction parallel to a surface of the semiconductor substrate. The two detector terminal doping regions are arranged at least partly in a terminal region of the well. The detection of the electromagnetic radiation is based on a generation of free charge carriers by the electromagnetic radiation in a detection region of the well. The transfer gates control a transfer of free charge carriers to be or not to be evaluated in a region of the well. The collection gate collects free charge carriers in the stated region of the well.

### CROSS-REFERENCE TO RELATED APPLICATIONS

This application claims priority from German Patent Application No. 102011076635.9, which was filed on May 27, 2011, and is incorporated herein in its entirety by reference.

### BACKGROUND OF THE INVENTION

The present application relates to detectors for detecting electromagnetic radiation which are based on a photo effect caused in a semiconductor material. Further, the application relates to a method for producing a detector and a method for detecting electromagnetic radiation.

Many industrial applications necessitate linear photosensors (row sensors) having high sensitivity and low noise or good noise behavior. Current improvements in the field of CMOS imaging (“complementary metal oxide substrate” imaging) allow the development and production of such sensors by means of standard existing CMOS technology at low cost, while allowing full integration of the associated sensor electronics on the same chip.

Apart from low noise, some applications also necessitate fast response, multiple shutter option, non-destructive readout and a large photoactive area. Relatively new developments in this area are so-called lateral drift-field photodetectors, as they are disclosed, for example, in the German patent specification DE 10 2009 020 218 B3. By a rising doping profile in a detection region of such a photodetector, it is achieved that photo-generated charge carriers specifically drift fast mainly in one direction, facilitating fast readout of the photodetector. Fields of application for row detectors or sensors based on CMOS technology having low noise, high velocity, multiple shutter option, non-destructive readout, a large photoactive area and a lateral drift field are:

discharge-induced spectrography

laser-induced spectrography

X-ray spectroscopy

material examination

fluorescence imaging

three-dimensional inspection/positioning systems

medical spectroscopy

scientific applications

For several spectroscopy and other similar applications where CMOS photosensors are used or provided, one of the main requirements is, for example, sufficient optical sensitivity also in the ultraviolet (UV) part of the spectrum (X=130 nm to 400 nm), non-destructive readout allowing signal monitoring, charge accumulation across several integration periods, and even noise reduction, for example by up-the-ramp-averaging technique, as well as the option of introducing several integration windows and multiple shutters with the ability to differentiate between individual pixels. The main object in this type of application is not the generation of a digital image, but being able to detect incident radiation and to measure its exact radiation intensity value in the optical spectrum from UV to near infrared (NIR) of the spectrum, i.e. approximately from X=130 nm to 1100 nm.

For considering the plurality of requirements for different applications, high versatility and flexibility is necessitated both with regard to technology and development aspects, in particular when the detectors are to be produced with the help of CMOS technology. This technology offers signal processing on a pixel level (“in-pixel processing”), abilities for addressing individual pixels, the “camera-on-a-chip” approach, and relatively low costs compared with other solid-body imaging technologies and in particular compared to the approach of photo-multiplier tubes, PMT, frequently used in spectrography.

Up to now it is one of the main advantages of PMT technology that, although it is much more expensive than semiconductor technology, it has the ability of almost immediate time discrimination by integrating the incoming signals. This allow the discrimination or differentiation between “desired” and “undesired” photo-induced charge carriers, which is a frequently occurring requirement in laser-triggered or discharge-triggered spectrography.

The currently known semiconductor-based approaches, normally concentrating on charge-coupled devices, CCD, both front and back side illuminated, offer very acceptable performances when compared to the photo-multiplier tubes with regard to spectral responsivity and signal-to-noise ratio or dynamic range. Still, there is an additional problem that occurs in spectrographic applications and in particular in material analysis, in that different chemical compounds have different reflectance values and hence generate very different photo signals. In practice, this means that specific elements reflect so strongly that the radiated pixel is almost immediately saturated, while other elements reflect so weakly that the signal is not strong enough to be detected at all. Defining a single charge integration window for both cases can be extremely difficult. Therefore, monitoring the output signals of every single pixel individually is a must, as well as the possibility of defining the starting point and the length of the integration window. Both processes are almost impossible to achieve by standard CCD approaches due to the missing abilities of non-destructive readout and the option of random pixel addressing. These two aspects are advantages of a CMOS approach.

Regarding CMOS sensors based on active pixels (CMOS APS), the same allow non-destructive readout, real ability for correlated double sampling for minimizing low-frequency noise, kTC reset noise, random pixel addressing, low dark current due to, for example, standard silicon surface determination in “pinned” photodiodes (PPD) or of buried control electrodes (buried gates) in photo gate-based (PG) pixels.

The great challenges in all these approaches are, however, the provision of abilities for correct time discrimination or differentiation and for charge separation made possible, for example, by photo-multiplier tubes. These aspects become even more important when they are applied to a row sensor having pixel lengths that can oscillate between several hundred micrometers and even several millimeters, which adds an additional problem regarding dark current and other leaking mechanisms, when integration times are involved that vary between several hundred microseconds and several seconds.

Some of these aspects can be solved when a lateral drift field is induced in the photoactive region of a CMOS-based active photosensor based on the charge transfer principle, which allows non-destructive readout, charge accumulation via several integration periods and monitoring of the output signal. These types of CMOS devices are conventional as mentioned in the above-stated German patent number DE 10 2009 020 218 B3 (by the same inventors as the presently disclosed technical teaching) for pixels having large photoactive regions, where an intrinsic drift field is induced in the pinned part of the device by a concentration gradient that is generated in the well of the opposite doping type as the silicon substrate in the direction of the non-pinned part of the detector. The photodetector comprises a buried collection electrode or buried collection gate (CG) and a buried transfer control electrode or buried transfer gate (TG) and finally a floating diffusion of the same doping type as the mentioned well. As one example, frequently, in laser-induced or discharge-induced spectroscopy, beginning with the laser impulse or the discharge impulse, electromagnetic radiation which is undesired or to be read out separately occurs for a specific time period, since it is, for example, generated mainly by plasma developed during the laser or discharge impulse and hence allows no or only a few conclusions or conclusions to be considered separately regarding the material to be examined. The charge carriers generated due to this electromagnetic radiation are also undesired or to be considered and read out separately for the purposes of a specific measurement. Only after that charge carriers develop that are desired or are to be read out separately. It would be desirable to provide a semiconductor-based photodetector by which the charge carriers generated within a first time interval can be separated from the charge carriers generated within a second or several following time intervals. In most currently used semiconductor-based photodetectors, this already fails due to the fact that removing the charge carriers is merely based on a relatively slow thermal diffusion, so that the charge carriers that are desired or develop later are already generated while a large part of the charge carriers generated within a specific previous time interval is still present in the detection region of the photodetector. Further, in currently known photodetectors, the separation of charge carriers cannot be combined with a charge accumulation across several integration periods, since typically, with every integration cycle, charge carriers that are to be considered separately develop again. Thus, there is a need for detectors detecting electromagnetic radiation combining the ability of charge carrier accumulation across several integration periods with the option of sorting the charge carriers within an integration cycle.

### SUMMARY

According to an embodiment, a detector for detecting electromagnetic radiation may have: a semiconductor substrate of a first doping type; a well in the semiconductor substrate, wherein the well is of a second doping type, wherein the first doping type and the second doping type are different, and wherein the well has a rising dopant concentration in a direction parallel to a surface of the semiconductor substrate; two or more detector terminal doping regions arranged at least partly in the well in a terminal region of the well, wherein the detector terminal doping regions are of the same doping type as the well, wherein the detection of the electromagnetic radiation is based on a generation of free charge carriers by the electromagnetic radiation in a detection region of the well having a maximum dopant concentration that is lower than a maximum dopant concentration of the terminal region of the well; two or more transfer gates electrically insulated from the semiconductor substrate for controlling a transfer of free charge carriers to be evaluated in a region of the well, wherein the transfer gates are each arranged in a region of the well between one of the detector terminal doping regions and the detection region; and a collection gate for collecting free charge carriers in a region of the well, wherein the collection gate is electrically insulated from the semiconductor substrate and is arranged in a region of the well adjacent to the detector terminal doping regions, the transfer gates and the detection region.

According to another embodiment, a method for producing a detector may have the steps of: providing a semiconductor substrate of a first doping type; generating a well in the semiconductor substrate, wherein the well is of a second doping type different to the first doping type, and wherein the well has a rising dopant concentration in a direction parallel to a surface of the semiconductor substrate; generating at least two detector terminal doping regions arranged at least partly in the well in a terminal region of the well, wherein the detector terminal doping regions are of the same doping type as the well, wherein the well has a detection region having a maximum dopant concentration which is lower than a maximum dopant concentration of the terminal region of the well; generating at least two transfer gates electrically insulated from the semiconductor substrate for controlling a transfer of free charge carriers to be evaluated in a region of the well, wherein the transfer gates are each arranged in a region of the well between the at least two detector terminal doping regions and the detection region; and generating a collection gate for collecting free charge carriers in a region of the well and for generating a constant electrostatic potential effecting an even distribution of the charge carriers collected below the collection electrode between several detector terminal doping regions, each via a transfer gate, wherein the collection gate is arranged in a region of the well adjacent to the detector terminal doping regions, the transfer gates and the detection region.

According to another embodiment, a method for detecting electromagnetic radiation may have the steps of: generating free charge carriers by the electromagnetic radiation in a detection region of a well, wherein the well is arranged in a semiconductor substrate, wherein the semiconductor substrate is of a first doping type and the well of a second doping type, wherein the first doping type and the second doping type are different, and wherein the well has a rising dopant concentration in a direction parallel to the surface of the semiconductor substrate; collecting the free charge carriers in a collection region of the well arranged at least partly in the well in a terminal region of the well, or in two or more detector terminal doping regions connected to the collection region of the above-stated well by means of the allocated transfer gates; transferring the charge carriers collected in the collection region of the well to one or several detector terminal doping regions by means of the associated transfer gates; determining whether the free charge carriers collected in the detector terminal doping regions correspond to at least one condition for charge carriers to be evaluated; depending on whether the free charge carriers collected in the detector terminal doping regions correspond to the at least one condition: a) repeating generating, collecting and transferring the charge carriers as described above, or b) outputting detector output signals corresponding to an accumulated amount of charge in one of the detector terminal regions when the accumulated amount of charge has reached or exceeded a charge threshold.

An embodiment according to the technical teaching disclosed herein provides a detector for detecting electromagnetic radiation. The detector comprises a semiconductor substrate of a first doping type and a well in the semiconductor substrate, wherein the well is of a second doping type. The first doping type and the second doping type are different and the well comprises a rising dopant concentration in a direction parallel to a surface of the semiconductor substrate. Further, the detector includes at least two detector terminal doping regions arranged at least partly in the well in a terminal region of the well and being of the same doping type as the well. Detection of electromagnetic radiation is based on a generation of free charge carriers by the electromagnetic radiation in a detection region of the well comprising a maximum dopant concentration, which is lower than a maximum dopant concentration of the terminal region of the well. The detector also includes at least two transfer gates electrically insulated from the semiconductor substrate for controlling a transfer of free charge carriers to be evaluated into a region of the well, wherein the transfer gates are arranged in a region of the well between the detector terminal doping regions and the detection region. Further, the detector includes a collection gate for collecting free charge carriers in the stated region of the well and for generating a constant electrostatic potential in order to be able to distribute the generated charge carriers evenly between the different detector terminal doping regions by means of respective transfer gates, wherein the collection gate is electrically insulated from the semiconductor substrate and is arranged in a region of the well adjacent to the detector terminal doping regions and the detection region.

Embodiments according to the technical teaching disclosed herein are based on the core idea that the charge carriers to be considered for detecting the electromagnetic radiation are transferred from a collection region to the detector terminal doping regions, whereas the charge carriers to be considered separately for detection are brought, within a separate evaluation method, from the collection region to another detector terminal doping region. In one case, this takes place by transferring charge carriers collected in the collection region of the detector by means of the transfer gate to the detector terminal doping region when, within the collection region, mainly charge carriers are present that are to be considered for detection and evaluation of the electromagnetic radiation. In the other case, the charge carriers collected in the collection region are transferred to another respective detector terminal doping region by means of another existing transfer gate, when the collected charge carriers are mainly such charge carriers that are to be considered separately for detection or evaluation of the electromagnetic radiation or that are not to be considered or evaluated at all. Since the different charge carrier types occur, for example, in different subintervals of one integration cycle each, selection of charge carriers to be evaluated can be obtained by the fact that control signals for each transfer gate are substantially synchronized with the time periods when charge carriers to be evaluated or charge carriers not to be evaluated or to be evaluated separately predominate in the collection region of the detector. In order to avoid that the charge carriers to be evaluated and the charge carrier not to be evaluated or to be evaluated separated already excessively mix within the detection region of the detector, it is ensured within the well that the charge carriers are accelerated in the direction of higher dopant concentrations by means of the rising dopant concentration. Thus, even without applying external electric potentials, movement of the free charge carriers in a desired direction can be caused. By the dopant gradient within the well, a drift field can be generated, which can accelerate charges in the whole detection region, for example also in the case of detectors having a large detection region. Thus, charge carrier transport is not only limited to thermal diffusion but can hence be performed considerably faster. Thereby, the response velocity of the detector can be increased significantly and/or the response time can be reduced. Since, due to a laser or discharge impulse, typically at first mainly undesired charge carriers or charge carriers that are not to be evaluated or only to be evaluated separately develop during a first phase of an integration cycle, the same can diffuse quickly out of the detection region into the collection region and be brought from there specifically into a first detector terminal doping region. The charge carriers to be evaluated generated shortly after that in the detection region can themselves be brought specifically out of the detection region into a second detector terminal doping region via the collection region, typically during a second phase of a respective integration cycle. The charge carriers to be evaluated can now be collected in one of the detector terminal doping regions across several integration cycles and in this way be integrated to an overall charge until the overall charge is sufficient to be meaningful enough for the radiation intensity of the detected electromagnetic radiation Likewise, possibly existing charge carriers to be evaluated separately can be collected in a different detector terminal doping region. Regarding the detection region, the collection region and/or the detector terminal region, the detector can be dimensioned such that with strong incident electromagnetic radiation, very few integration cycles or only a single integration cycle is sufficient to collect a sufficiently large amount of charge that can be evaluated without overloading the detector, i.e. that the same passes into a saturation region where a reliable statement on the detected radiation intensity can no longer be made. With weaker incident electromagnetic radiation, however, integration can be performed across successive integration cycles until an overall amount of charge collected in a detector terminal doping region is large enough for a relatively reliable evaluation.

Several embodiments according to the invention relate to a method for producing a detector. The method includes providing a semiconductor substrate of a first doping type and generating a well in the semiconductor substrate, wherein the well is of a second doping type. The first doping type and the second doping type are different and the well comprises a rising dopant concentration in a direction parallel to the surface of the semiconductor substrate. Further, the method includes generating at least two detector terminal doping regions arranged at least partly in the well in a terminal region of the well, the detector terminal doping regions being of the same doping type as the well. The detector terminal doping regions comprise a maximum dopant concentration, which is lower than a maximum dopant concentration of the terminal region of the well. Further, at least two transfer gates are generated that are each electrically insulated from the semiconductor substrate. The transfer gates serve to control a transfer of free charge carriers to be evaluated in a region of the well, wherein the transfer gate is arranged in a region of the well between the detector terminal doping region and the detection region. Thereby, another transfer gate serves to control a transfer of free charge carriers not to be evaluated or to be evaluated separately in a region of the well, wherein this second transfer gate is arranged in a region of the well between the second detector terminal doping region and the detection region. Further, the method comprises generating a collection gate for collecting free charge carriers and for generating a constant electrostatic potential effecting an even distribution of the generated free charge carriers between the different detector terminal doping regions in a region of the well, wherein the collection gate is arranged in a region of the well adjacent to the detector terminal doping regions, the transfer gates and the detection region.

Several further embodiments of the technical teaching disclosed herein relate to a method for detecting electromagnetic radiation. The method includes generating free charge carriers by the electromagnetic radiation in a detection region of a well, wherein the well is arranged in a semiconductor substrate. The semiconductor substrate is of a first doping type and the well is of a second doping type. The first doping type and the second doping type are different. The well comprises a rising dopant concentration in a direction parallel to the surface of the semiconductor substrate. Further, the method for detecting electromagnetic radiation includes collecting the free charge carriers in a collection region of the well arranged at least partly within the well, in a terminal region of the well. Additionally, the method includes determining whether the free charge carriers collected in the collection region correspond to at least one condition for charge carriers to be evaluated. Further, the method comprises evaluating the result of the determination. Accordingly, the method comprises a conditional action of transferring the collected free charge carriers to be evaluated from the collection region to one of the detector terminal doping regions if the collected free charge carriers correspond to the at least one condition. The respective detector terminal doping region is arranged at least partly in the well in the terminal doping region of the well and is of the same doping type as the well. The method also includes a second conditional action of causing a different charge transfer of the collected free charge carriers not to be evaluated or to be evaluated separately from the collection region to another detector terminal doping region if the free charge carriers collected in the collection region do not correspond to the at least cone condition or correspond to a second condition.

According to further embodiments of a method for detecting electromagnetic radiation, such a method comprises: generating free charge carriers by the electromagnetic radiation in a detection region of a well, wherein the well is arranged in a semiconductor substrate, wherein the semiconductor substrate is of a first doping type and the well of a second doping type, wherein the first doping type and the second doping type are different, and wherein the well comprises a rising dopant concentration in a direction parallel to the surface of the semiconductor substrate; collecting the free charge carriers in a collection region of the well arranged at least partly in a terminal region of the well; and determining whether the free charge carriers collected within the collection region correspond to at least one condition for charge carriers to be evaluated. If the collected free charge carriers correspond to the at least one condition, transferring the collected charge carriers to be evaluated from the collection region to a detector terminal doping region, which is arranged at least partly in the well in the terminal doping region of the well, will take place. If the collected free charge carriers do not correspond to the at least one condition or correspond to another condition, the collected charge carriers are qualified as charge carriers to be evaluated separately and transferring the collected charge carriers to be evaluated separately from the collection region to the second detector terminal doping region. which is arranged partly in the well in the terminal doping region, will follow, wherein the second detector terminal doping region is of the same doping type as the well.

The dependent claims relate to optional features of the technical teaching disclosed herein. The method for producing a detector can include further optional features or actions relating to the generation of optional apparatus features disclosed in the dependent apparatus claims or also in the following description. The method for detecting electromagnetic radiation can include optional features relating to optional apparatus features of the dependent apparatus claims or to respective optional features of the description.

According to the technical teaching disclosed herein, an approach for row sensor applications is used, according to which at least one additional transfer gate or transfer gate (TG) and an addition floating diffusion (FD) or detector terminal doping region are responsible for collecting the “desired” photogenerated charge carriers or to drain the photo generated charge carriers that are “undesired” or to be evaluated separately. For a better differentiation, the at least one additional transfer gate and the at least one additional floating diffusion are also referred to as “drain gate” and “charge drain doping region” according to their function. The dopant concentration profile within the generated well can be implemented for lengths of the detection region ranging from several hundred micrometers to several millimeters, wherein transfer times of merely several hundred microseconds can be expected. In comparison, pixels based on a PPD or a buried PG for the same geometries would result in transfer times of at least several hundred microseconds, which would at least greatly impede their usage for this type of objects or even make it impossible.

### BRIEF DESCRIPTION OF THE DRAWINGS

Embodiments of the present invention will be detailed subsequently referring to the appended drawings, in which:

FIG. 1A is a schematic longitudinal sectional view and a schematic top view of a detector according to an embodiment of the technical teaching disclosed herein;

FIG. 1B is a schematic cross-sectional view of the detector of FIG. 1A;

FIG. 2 is a schematic circuit diagram of a pixel readout and control circuit according to an embodiment of the technical teaching disclosed herein;

FIG. 3a is a schematic illustration of an electrostatic potential profile across a detector in a direction perpendicular to a main surface of the detector at the collection gate (CG) or the well;

FIG. 3b is a schematic illustration of an electrostatic potential profile in parallel to the substrate surface along the cross-section a-a′ of FIG. 3a;

FIG. 4 is a schematic illustration of a lateral dopant concentration curve;

FIG. 5 is a schematic top view of a detector according to a further embodiment of the technical teaching disclosed herein;

FIG. 6 is several schematically illustrated waveforms of several signals that can occur in a detector according to the technical teaching disclosed herein;

FIG. 7 is a schematic circuit diagram of a pixel readout and control circuit according to a further embodiment of the disclosed technical teaching;

FIG. 8 is a schematic circuit diagram of a pixel readout and control circuit according to a further embodiment of the disclosed technical teaching;

FIG. 9 is a schematic circuit diagram of a detail of the pixel readout and control circuit for providing control signals for a detector;

FIG. 10 is a schematic top view of an array of row detectors;

FIG. 11 is a schematic flow diagram of a method for producing a detector; and

FIG. 12 is a schematic flow diagram of a method for detecting electromagnetic radiation.

### DETAILED DESCRIPTION OF THE INVENTION

In the present application, the same reference numbers are used in parts for objects and functional units comprising the same or similar functional characteristics.

A novel detector for electromagnetic radiation is suggested which is suitable in particular for row sensors but also for other types of sensors. As regards several features, one pixel of such a detector is based on the lateral drift-field photodetector (LDPD) known from German patent No. 10 2009 020 218 B1 of the same inventors. The lateral drift-field photodetector comprises a pinned photodiode area and a non-pinned area. Within the disclosure herein, the lateral drift detector is modified further, to fulfil, for example, at least one of the above-stated functions.

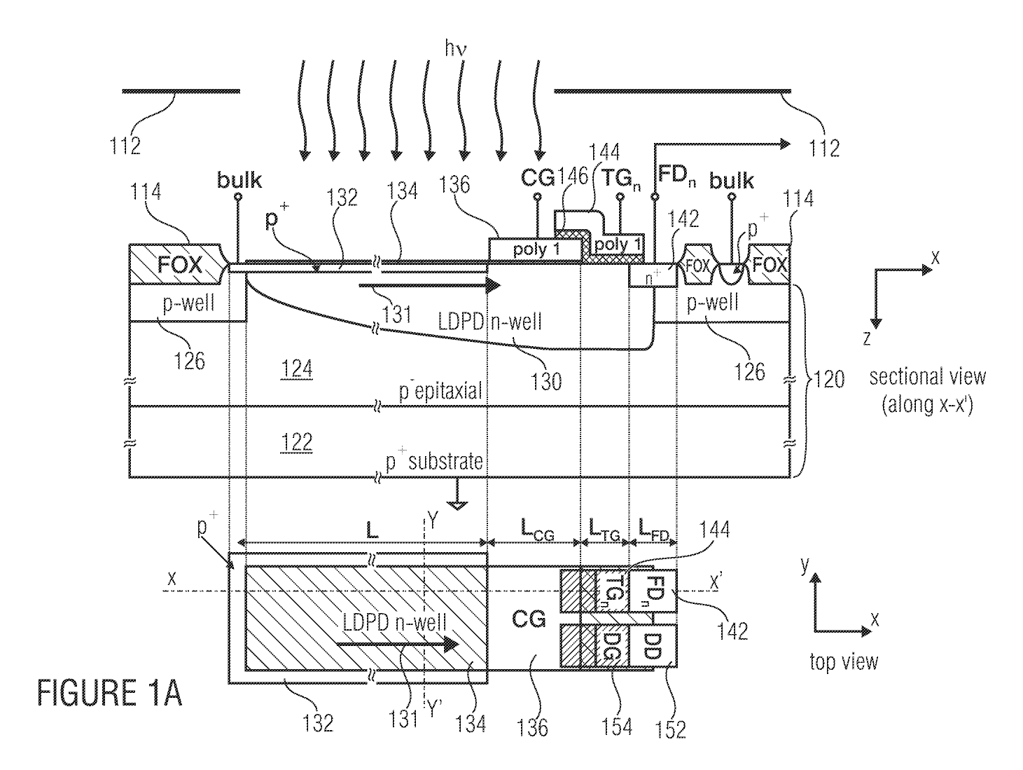

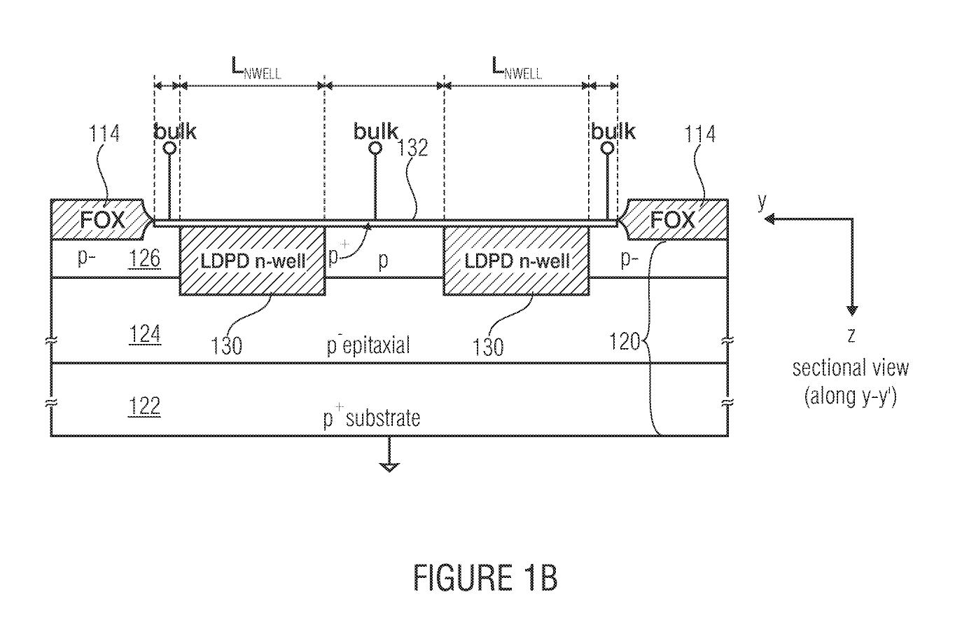

The pinned area of the detector comprises a well of a doping type different from that used for the silicon substrate in which the same is implemented. The well shows a non-uniform lateral doping profile, as is illustrated in the top right cross-sectional illustration in FIG. 1 (section in the xz plane). The pinned area remains completely depleted during operation, when it is sandwiched between the substrate and a grounded, highly doped layer of the same doping type as the substrate which is located on the surface of the already mentioned well. This part of the LDPD device is similar to the so-called pinned photodiode (PPD) as described by Lee et al. in U.S. Pat. No. 5,625,210 which provides low dark current and good quantum yield in the blue spectral domain. The same also has other advantages with regard to signal-to-noise ratio and a charge voltage conversion factor. Additionally, according to the technical teaching disclosed herein, deviating from the teaching described in U.S. Pat. No. 5,625,210, an intrinsically generally drift field is induced in the direction of the readout node and the non-pinned region of the detector based on the produced dopant concentration gradient in this region. A collection gate (CG), one or several transfer gates TG and one or several floating diffusions FD, as well as a diffusion directly connected to a higher electric potential and hence called draining diffusion, which cannot be seen in the top sectional view in FIG. 1A, are each part of the non-pinned part of the photodetector. A two-dimensional layout example of the detector can be seen in the top view in FIG. 1A. Here, L indicates the length of the pixel (typically several hundred micrometers), L_{CG} the length of the collection gate CG, L_{TG} the length of the transfer gates, and L_{FD} the length of the floating diffusions or the draining diffusion.

FIGS. 1A shows a schematic longitudinal sectional view and a top view of a detector for detecting electromagnetic radiation according to the technical teaching disclosed herein. The illustrated photodetector can be referred to as a lateral drift-field photodetector, which can be used, for example, for row sensor applications such as spectroscopy. The photodetector has a high response velocity or a low response time, low noise, low dark current and the option of non-destructive readout.

FIG. 1B shows a cross-section through the photodetector in the yz plane. The cross sectional view illustrated at the top of FIG. 1A represents a schematic cross-section in the xz plane, i.e. basically a longitudinal section of the photodetector. In the top view illustrated at the bottom in FIG. 1A the position of the longitudinal section illustrated at the top in FIG. 1A is shown by means of the dotted line indicated by X-X′. Likewise, the top view shows the position of the cross-section illustrated in FIG. 1B by means of the dotted line indicated by Y-Y′.

Starting with the longitudinal sectional view shown at the top in FIG. 1A, it can be seen that the detector includes a substrate 120 which again includes several layers (here three layers). The substrate 120 is p-doped, so that a first doping type is the p doping type in the present embodiment. A lowest one of the three layers of the substrate 120 is formed by a substrate block 122 which is highly doped with the first doping type (p⁺) in the present example. Further, the substrate 120 comprises an epitaxial layer 124 weakly doped with the first doping type (p⁻ epitaxial). This epitaxial layer 124 can have been deposited on the substrate block 122 during an early phase of a production process. As a third layer, the substrate 120 includes a slightly p-doped layer 126. The detector also includes a well 130 which is of a second doping type. Correspondingly, in the embodiment shown, the well is n-doped. A dopant concentration within the well 130 rises along the longitudinal direction (i.e. parallel to the x axis), as indicated by arrow 131. As is shown in FIG. 1, in the context of the rising doping concentration, the depth of the well 130 can also rise in the z direction, which can be caused, for example, by the characteristics of the selected doping process. Other doping processing can achieve, for example, that the depth of the well 130 remains substantially constant across the whole length L+L_{CG}+L_{TG}. At least part of the surface of the well 130 facing away from the substrate 120 is covered by a heavily p⁺-doped layer 132. This p⁺-doped layer 132 is connected at its left end with the more weakly p-doped substrate layer 126. Further, the p⁺-doped layer 132 comprises a bulk contact, via which the p⁺ layer 132 and also the substrate 120 can be pulled to a specific electric potential. In the region where the p⁺ layer 132 is provided, the photodetector has the structure of a pinned photodiode. The p⁺-doped layer 132 is typically transmissive for the electromagnetic radiation to be detected, so that a detection region of the detector extends substantially in the region of the well 130 below the p⁺-doped layer 132.

The electromagnetic radiation to be detected is indicated in FIG. 1A by bent arrows Ku. A metal shielding 112 has the effect that the electromagnetic radiation by mainly impinges on the detector surface only in the detection region. Here, the metal shielding 112 is illustrated at a distance from the actual detector. Alternatively, the metal shielding 112 can also be deposited directly on a surface of the actual detector. The metal shielding 112 prevents photogenerated charge carriers from being generated in regions of the photodetector other than the detection region, which could result in corruption of the detection result, in particular when these are regions of the detector downstream of the detection region and serving to latch generated charge carriers.

An electrode assembly is likewise arranged on the surface of the well 130 facing away from the substrate 120. This electrode array is arranged at an end of the well 130 which is in the longitudinal direction where the dopant concentration is high compared to the other region of the well 130. The electrode array comprises a collection gate 136, consisting of polysilicon in the embodiment shown, which was deposited on the surface of the well 130 during production during a first phase for depositing polysilicon. The electrode assembly also comprises a transfer gate 144, also consisting of polysilicon in the embodiment illustrated. However, the polysilicon of the transfer gate 144 had been deposited during a second depositing phase for polysilicon, since an insulating layer 134 is provided between the collection gate 136 and the transfer gate 144, which is deposited between the first polysilicon layer for the collection gate 136 and the second polysilicon layer for the transfer gate 144. As can be seen in FIG. 1, the transfer gate 144 partly overlaps with the collection gate 136 in the x direction. In this way, an electric field generated by the transfer gate 144 also has an effect on the region below the collection gate 136, whereby a transfer of collected charge carriers in the region below the collection gate 136 to an adjacent region of the detector, accessible by means of respective control of the transfer gate 144, can be performed more quickly. The transfer gate 144 can exist several times, wherein several transfer gates 144 can be lined up, for example, in the y direction. At the end of the well 130, towards which the dopant concentration 131 rises, the detector includes a floating diffusion 142 which is heavily n-doped (n⁺). As long as no electric potential that differs significantly from an electric potential of the well 130 is applied to the transfer gate 144, the free charge carriers drift in the direction of the rising dopant concentration up to the floating diffusion 142, since the floating diffusion 142 comprises a maximum dopant concentration which is higher than a maximum dopant concentration in the detection region of the well 130. By applying a suitable electric potential that differs from the electric potential of the well 130 to the transfer gate 144, the transfer of free charge carriers from the detection region into the floating diffusion 142 can be specifically prevented at times.

Both the collection gate 136 and the transfer gate 144 are electrically insulated from the well 130. The collection gate 136 can be controlled by means of a contact CG (“collection gate”) with a collection gate signal. A transfer gate signal can be supplied to the n^{th} transfer gate 144 (as long as several transfer gates exist) via a contact TGₙ (“transfer gate n”). By a signal pattern for the collection gate 136 and the transfer gate 144, it can be achieved that the free charge carriers collected below the collection gate 136 are supplied to the floating diffusion or the detector terminal dopant region 142 by opening the transfer gate 144. Supplying charge carriers to the detector terminal doping region 142 is reflected in a change of electric potential of the detector terminal doping region 142. The respectively predominant electric potential in the detector terminal doping region 142 can be read out via a contact FDₙ (“floating diffusion n”), wherein typically a readout circuit having a high input resistance is used.

In the longitudinal sectional view of the detector shown in FIG. 1A at the top, it can be seen that a field oxide (FOX) array 114 is located on the right of the detector terminal doping region 142. The field oxide array 114 is discontinuous at one location for a p⁺-doped region connected to a further bulk contact. Via the bulk contact, the substrate 120 can be pulled to a specific electric potential in the region around the detector terminal doping region 142. For example, the left bulk contact and the right bulk contact that can be seen in the longitudinal sectional view of the detector in FIG. 1A can substantially be at the same electric potential. Since the detection region of the detector can be relatively long (e.g. from a hundred micrometers to several millimeters), the substrate 120 is substantially pulled to a uniform electric potential by the two illustrated bulk contacts and possibly further bulk contacts, despite the large extension in the longitudinal direction.

In the top view of the detector at the bottom in FIG. 1A, a second transfer gate 154 serving as a draining gate is illustrated beside the first transfer gate 144. The second transfer gate 154 can essentially be structured analogously to the first transfer gate 144. The region of the well 130 which is below the collection gate 136 can be connected, in an electrical sense, by respective control of the second transfer gate 154, to a second detector terminal doping region 152 for a transfer of the collected free charge carriers, and can be separated, in an electrical sense, from the same for preventing the transfer. The first detector terminal doping region 142 and the second detector terminal doping region 152 are n⁺-doped in the embodiment illustrated. For example, the p-doped substrate layer 126 can extend up to the surface between the first detector terminal doping region 142 and the second detector terminal doping region 152 in order to electrically insulate the first detector terminal doping region 142 and the second detector terminal doping region 152 from one another. Other measures for electric insulation of the first detector terminal doping region 142 and the second detector terminal doping region 152 are also possible, such as an extension of the field oxide 114 between the two stated regions.

In the area of the detection region, the top view shows the insulating layer 134. From the p⁺-doped layer, across which the detection area is pinned on one side, the edge projecting beyond the insulation layer 134 can be seen on three sides. The insulation layer 134 continues below the collection gate 136, the transfer gate 144 and the draining gate 154, to then respectively cover part of the first detector terminal doping region 142 or the second detector terminal doping region 152 (see in particular the longitudinal sectional view in FIG. 1).

The detection region has an extension L in the longitudinal direction; the collection gate 136 has an extension L_{CG} in the longitudinal direction, the first transfer gate 144 and the second transfer gate 154 each have an extension L_{TG} in the longitudinal direction. In the illustrated embodiment, the first detector terminal doping region 142 and the second detector terminal doping region 152 also have an identical extension in the longitudinal direction L_{FA}.

The second detector terminal doping region or charge draining doping region 152 is typically permanently connected to a higher electric potential during operation, so that free charge carriers supplied to the second detector terminal doping region 152 directly drain in the direction of the higher electric potential. Since the free charge carriers are attracted by the higher electric potential, the draining transfer is relatively fast. In this way, the collection region below the collection gate 136 can be freed relatively quickly from free charge carriers that are undesired or not intended for detection or to be evaluated separately, in order to be ready for the charge carriers that are desired or intended for detection and arrive later. However, the decision whether a generated free charge carrier is to be considered for evaluating the detection or not depends on at least one criterion which can be user-defined. Thus, the differentiation is according to user-defined criteria, such as different time intervals, in which predominantly charge carriers to be considered for detection or not develop or arrive in the collection region.

FIG. 1B shows a cross-section through the detector. Two adjacent wells 130 can be seen, each having the width L_{NWELL}. Both wells 130 can open into a common collection region below the collection gate 136.

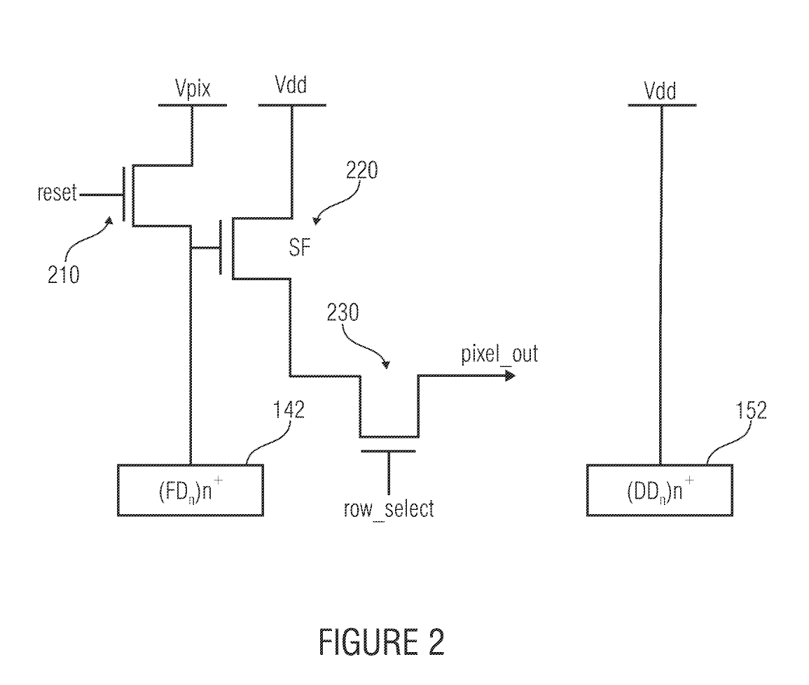

FIG. 2 shows the in-pixel readout circuits, wherein the detector terminal doping region 142 or, if several exist, each of the detector terminal doping regions 142 is connected to the source of a reset transistor, the signal of which can be read out by an in-pixel buffer which is structured as a source follower configuration (SF) and forms part of the pixel. The charge draining doping region 152 is, however, directly connected to a higher electric potential, here illustrated as V_{DD}. The reset transistor 210 is connected to an electric potential by means of its drain, indicated in FIG. 2 by Vₚᵢₓ. The gate of the buffer transistor 220 is connected to the source of the reset transistor 210. As long as the reset transistor 210 is non-conductive, an electric potential is applied to the gate of the buffer transistor 220 which is a function of the overall charge stored in the detector terminal doping region 142. Due to the amplification effect of the buffer transistor 220, the electric potential applied to the source of the buffer transistor 220 changes in dependence on the electric potential applied at its gate.

Further, the readout circuit comprises a row select transistor 230 controlled by a row select signal (“row_select”) and at the output of which the pixel output signal (“pixel-out”) is applied when the row selection transistor 230 is gated. In this manner, the pixel output signal can be read out from the detector for each pixel after respective selection by the row selection signal.

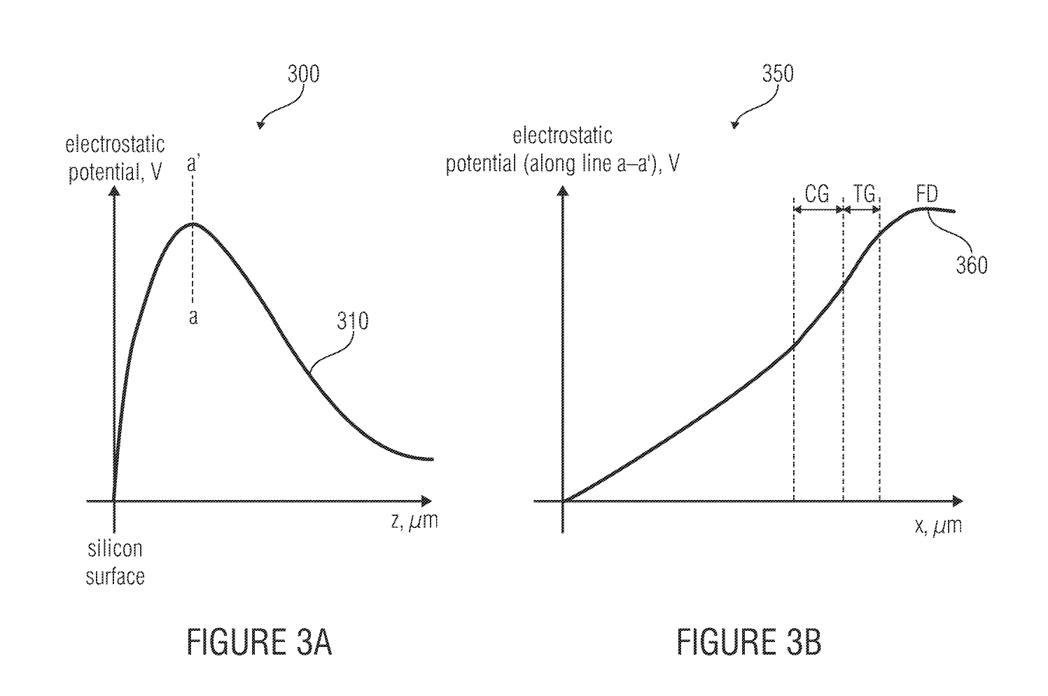

The fact that the collection gate is produced on top of the same well is similar to a buried photo gate, where the electrostatic potential maximum is at a distance from the silicon surface when a perpendicular section is made through the collection electrode, as can be seen from FIG. 3. FIG. 3a shows a schematic illustration 300 of an electrostatic potential profile 310 perpendicular to the surface of the substrate. The potential curve 310 shows a maximum at a significant distance to the substrate surface (or to the silicon surface when a silicon wafer is used as the substrate).

As a consequence, the number of charge carriers originating from the fast surface states and mixed with the already collected signal charge carriers can be reduced. Additionally, FIG. 3b shows a schematic illustration 350 of an electrostatic potential profile 360 parallel to the substrate surface along the cross-section a-a′ of FIG. 3a. The electrostatic potential rises from one end of the well 130 to a maximum in the region of the floating diffusions or the first detector terminal doping region 142 and the second detector terminal doping region 152.

Finally, by means of the transfer gate 144, a mechanism can be provided that can generate a potential barrier within the well 130, which can prevent the collected charge from being transferred to the adjacent detector terminal doping region 142 during the charge collection cycle, or that can enlarge the drift field which lets the collected charge carriers drift into the detector terminal doping region 142 during the readout cycle and the reset cycle. The detector terminal doping region 142 can, for example, be used as photo detector readout node and/or photo detector reset node.

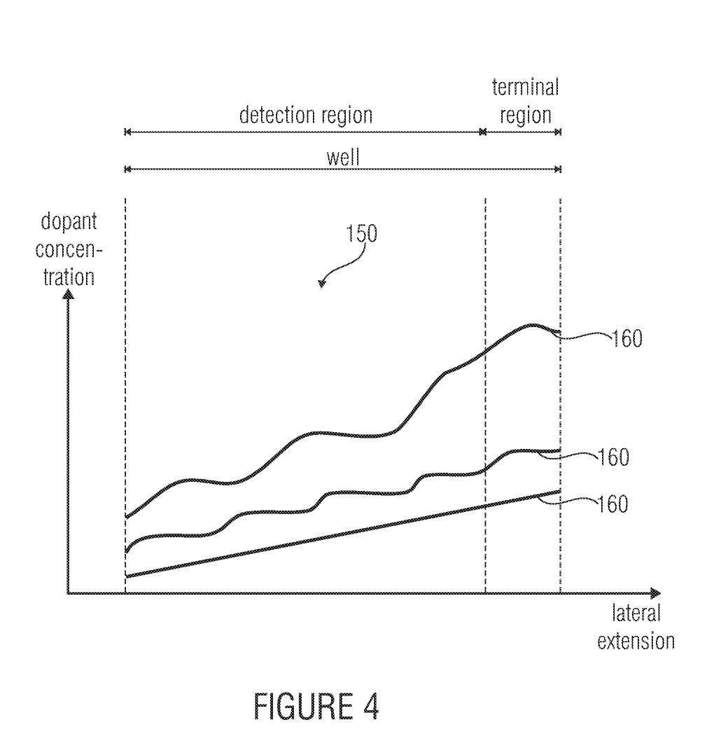

FIG. 4 shows a schematic illustration of a lateral dopant concentration curve. Thereby, the abscissa shows the lateral extension parallel to the surface of the semiconductor substrate 120 and the ordinate the dopant concentration of the well 130. The figure shows three examples of a dopant concentration curve 160 in the well. The dopant concentration can, for example, be rising monotonously, rising in a stepped manner, rising linearly or can comprise another form of rising. The dopant concentration can, for example, be lowest at one end of the well 120 and highest at the other end of the well 130 where, for example, the terminal region can be located. Alternatively, the terminal region can, for example, be in the center of the well 130 and the dopant concentration can rise from the edges of the well 130 towards the terminal region in the center of the well 130.

The detector terminal doping region 142, which is, for example, partly within the well, can, for example, have a higher dopant concentration than a maximum dopant concentration of the well 130 to allow a low-impedance terminal to a wiring level and at the same time to provide the highest electrostatic potential for collecting the free charge carriers. Further, the well 130 in the terminal region can have the maximum dopant concentration of the well.

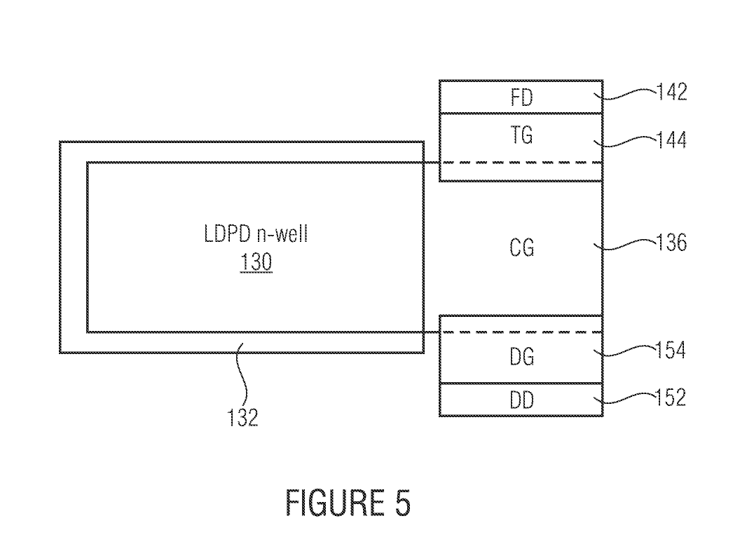

FIG. 5 shows a schematic top view of a detector according to a further possible embodiment, where the first detector terminal doping region 142 and the second detector terminal doping region 152 are arranged opposite with regard to the collection region. Thus, the first transfer gate 144 and the first detector terminal doping region 142 are attached to a first side of the collection region. At a second side opposing the first side, the second transfer gate 154 and the second detector terminal control region 152 are attached to the collection region. As in the embodiment illustrated in FIGS. 1A and 1B, in the embodiment according to FIG. 5, the first transfer gate 144 and the second transfer gate 154 can also partly overlap the collection region. In this embodiment, the collection region is also adjacent to the first detector terminal doping region 142, the second detector terminal doping region 152 and the detection region, since both the first detector terminal doping region 142 and the second detector terminal doping region 152 are arranged at least partly in the terminal region of the well 130 and are hence in contact with the well. The gates 144 and 154 extend typically above the regions where the first or second detector terminal doping regions 142 or 152 are in contact with the collection region. Apart from the illustrated arrangement, further arrangements of collection region, detection region, first and second detector terminal doping regions or charge draining doping region are possible, such as a triangular arrangement.

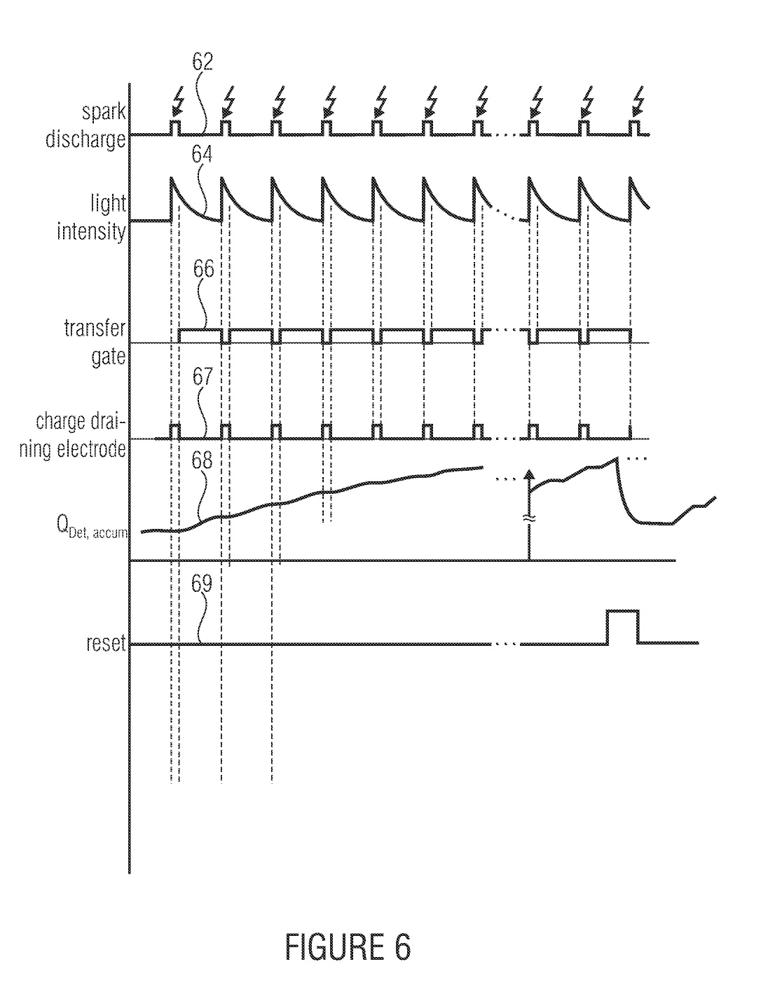

FIG. 6 shows schematically a series of time waveforms for illustrating the function of a detector according to the disclosed technical teaching. For the purpose of illustration and explanation, the case of application of a spark emission spectrometry is used. The uppermost waveform illustrated in FIG. 6 shows a spark discharge curve 62. At regular intervals, spark discharges are performed. Typical spark sequence frequencies are in a range up to 1000 Hz. The individual spark discharges are illustrated schematically as square-wave signals, but can also have other forms. An intensity waveform 64 represents the intensity of the electromagnetic radiation generated by the spark discharges. The electromagnetic radiation can, for example, be in the spectrum in the range of visible light as well as the adjacent regions (infrared and ultraviolet light). The type of material to be examined and the excitation by the spark discharge has an effect on the generated electromagnetic radiation, schematically shown by the light intensity waveform 64. In particular, it can happen that the radiation intensity is, at first, relatively high during spark discharge and drops after termination of the spark discharge. Further, it is possible that electromagnetic radiation results during specific phases of the spark discharge, which might be unsuitable for the purposes of spectrometry or is to be evaluated separately.

FIG. 6 also shows a schematic transfer control waveform 66 of a transfer control signal intended for controlling the transfer gate 144 and a schematic charge draining control waveform 67 of a charge draining control signal intended for controlling the draining gate 154 (i.e. the second transfer gate). When the transfer signal has the value “1” or “high”, the transfer gate has the effect that a conductive channel results between the collection region and the detection terminal doping region 142, so that free charge carriers can drift from the collection region into the detector terminal doping region 142. This drifting of free charge carriers is supported by the dopant concentration gradient. However, when the transfer signal has the value “0” or “low”, then the transfer gate 144 generates a barrier between the collection region and the detector terminal doping region 142. As a consequence, free charge carriers can no longer drift or diffuse from the collection region into the detector terminal doping region 142. As can be seen in FIG. 6, the transfer control waveform 66 comprises portions having the value “1”, where transfer of the free charge carriers into the detector terminal doping region 142 is possible. These sections occur once per spark discharge cycle, after the radiation intensity 64 has dropped from a maximum value, which typically occurs during the initial phase of the spark discharge cycle. In this way, for example, the free charge carriers developing during an initial phase of the spark discharge cycle are not transferred into the detector terminal doping region and are hence also not used for spectrometry. Only the free charge carriers developing later during the respective spark discharge cycle are transferred into the detector terminal doping region and are evaluated accordingly.

The charge draining control waveform 67 is illustrated in FIG. 6 essentially complementary to the transfer control waveform 66. Hence, the charge draining control waveform 67 comprises, in the initial phase of one spark discharge cycle each, a section with the value “1”, where the draining electrode connects the collection region with the charge draining control region. In this way, the free charge carriers that are in the collection region during this phase can drain into the charge draining doping region and are not used for measuring the radiation intensity. The transfer control waveform 66 and the charge draining control waveform 67 can simultaneously assume the value “0”, whereby the collection region is connected neither to the detector terminal doping region 142 nor to the charge draining doping region 152 in the sense of a transfer or draining transfer of the free charge carriers. Further, it is possible that the transfer control signal and/or the charge draining control signal comprises a phase shift with respect to the spark discharge curve 62. With the phase shift, for example, a delay between the spark discharge and the time when the free charge carriers reach the collection region can be compensated. A value of the phase shift that is as optimal as possible can be determined by calculation, simulation or experiments.

A further waveform shown in FIG. 6 schematically represents an overall charge 68 accumulated in the detector terminal region 142. The accumulated overall charge rises during the sub-phases of a spark discharge cycle when the collection region is connected to the detector terminal region 142 due to respective control of the transfer gate 144. In the other sub-phases when the collection region is connected to the charge draining control region 152, the overall charge in the detector terminal doping region stays essentially constant. Integrating the charge into the detector terminal doping region 142 can take place across several spark discharge cycles until a threshold is reached which indicates that the accumulated overall amount of charge is sufficient for a meaningful measurement.

A reset signal 69 is also illustrated in FIG. 6. The reset signal controls the reset transistor 210 (see FIG. 2). If the reset transistor 210 becomes conductive, the charges stored in the detector terminal doping region 142 drain, for example, to the potential Vdd illustrated in FIG. 2. In FIG. 6, it can be seen that the accumulated overall charge 68 decreases in the detector terminal doping region 142 when the reset signal 68 assumes the value “1”. Resetting the detector terminal doping region 142 essentially follows the discharge curve of a capacitor.

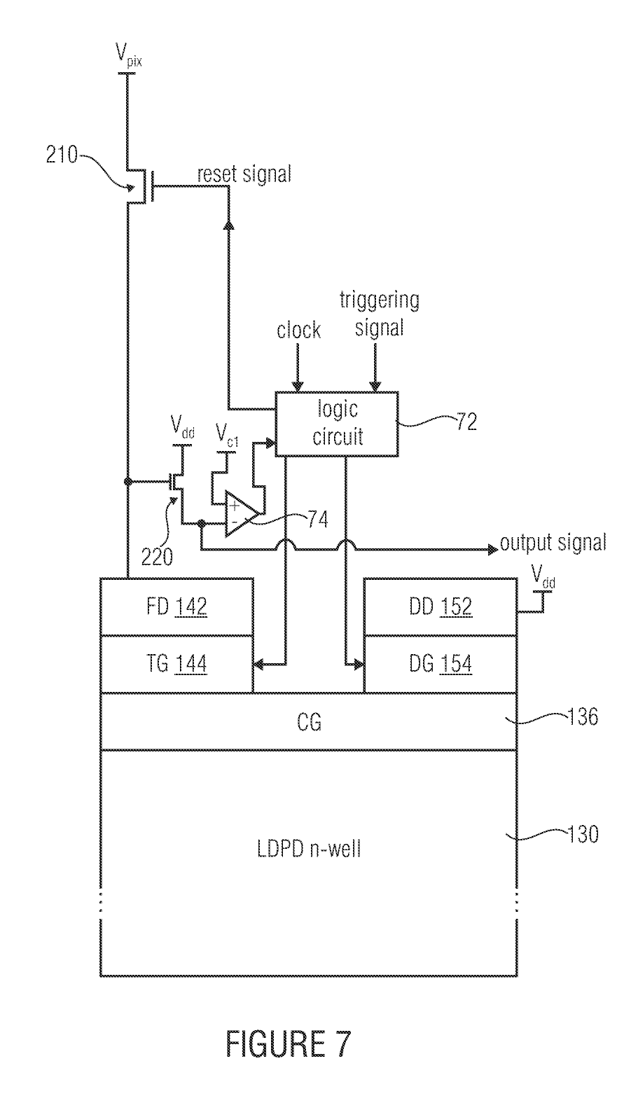

FIG. 7 shows a schematic circuit diagram of a pixel readout and control circuit according to a further embodiment of the disclosed technical teaching. In the bottom part of FIG. 7, the well 130, the collection gate 136, the transfer gate 144, the detector terminal doping region 142, the draining gate 154 and the charge draining doping region 152 are illustrated schematically. For generating control signals for the transfer gate 144 and the draining gate 154, the pixel readout and control circuit comprises a logic circuit 72, which can be implemented, for example, in CMOS technology. The logic circuit 72 also generates the reset signal for the reset transistor 210. As inputs, the logic circuit 72 comprises a clock signal input, a triggering signal input for receiving a measurement-triggering signal, and a comparison signal input. A comparison signal applied to the comparison signal input is formed by an analog comparison circuit, which comprises a comparator in the form of an operational amplifier 74. Other options for implementing a comparator are also possible. At its inverting input, the comparator 74 receives a voltage signal generated by the detector terminal doping region 142. The voltage signal corresponds to the overall charge accumulated in the detector terminal doping region 142. A reference or comparison voltage V_{c1} represents a second input signal for the comparator 74 which is applied to its non-inverting input. Depending on which relation the voltage signal provided by the detector terminal doping region 142 and the reference or comparison voltage V_{c1} have to each other, i.e. which of the two voltages is higher, a respective value results at the output of the comparator 74, which is provided to the logic circuit 72. In this way, the logic circuit 72 receives information on when the accumulated overall charge in the detector terminal doping region 142 exceeds a specific threshold. This information can be evaluated by the logic circuit 72, for example to perform a transition from a first operating state to a second operating state. The first operating state can correspond to a (repeated) accumulation of charge in the detector terminal doping region 142 across one or several discharge cycles. In the second operating state, the overall charge accumulated up to the time of switching from the first to the second operating state is essentially kept constant until the same is read out. The repeated accumulation can be performed by repeatedly opening the transfer gate 144, which can be controlled by the logic circuit 72. During the second operating state, the transfer gate 144 is constantly kept closed, so that no further charges can flow from the collection region into the detector terminal doping region. When a measurement cycle, which can comprise a plurality of discharge cycles, is terminated, the voltage applied to the detector terminal doping region 142 can be output as pixel output signal. The source follower transistor 220 serves to amplify and/or buffer the pixel output signal. It should be noted that the inverting input of the comparator 74 could also be connected directly to the detector terminal doping region 142, in particular when the comparator 74 comprises a high input resistance which only slightly loads the detector terminal doping region 142.

The start of a new measurement cycle is controlled by the triggering signal. During a measurement cycle, typically, a plurality of discharge cycles or laser impulse cycles are performed, which can depend, for example, on the clock signal, i.e. a discharge cycle is performed at every impulse of the clock signal. Other ratios between clock signal and discharge cycle are also possible. At the beginning of a new measurement cycle, the detector terminal doping region 142 is discharged, wherein the discharge can either have taken place at the end of the previous measurement cycle or at the beginning of the current measurement cycle. The discharge of the detector terminal doping region 142 is performed via the reset transistor 210 and a respective control by the logic circuit 72. Then, the pixel control circuit is in a first operating state and separates, during each discharge cycle, the charge carriers to be evaluated from the charge carriers not to be evaluated or to be evaluated separately. The charge carriers to be evaluated are collected in the detector terminal doping region, while the charge carriers not to be evaluated or to be evaluated separately are supplied to the charge draining doping region, from where they are typically directed to an electric potential (here V_{dd}). For this purpose, during each clock cycle, the draining gate 154 is opened at first, so that charge carriers not to be evaluated or to be evaluated separately can flow out of the collection region into the charge draining doping region 152. Then, the second transfer gate or draining gate 154 is closed and the transfer gate 144 is opened to transfer the charge carriers to be evaluated into the detector terminal doping region 142. This process is typically continued across several discharge cycles, until a previously determined number of discharge cycles have been performed or until an amount of charge exceeding a threshold has been accumulated in the detector terminal doping region. However, the case that only one discharge cycle is performed during one measurement cycle can also occur. By means of the source follower transistor 220, an electric voltage corresponding to the accumulated charge can be read out at the detector terminal doping region 142 as a pixel output signal.

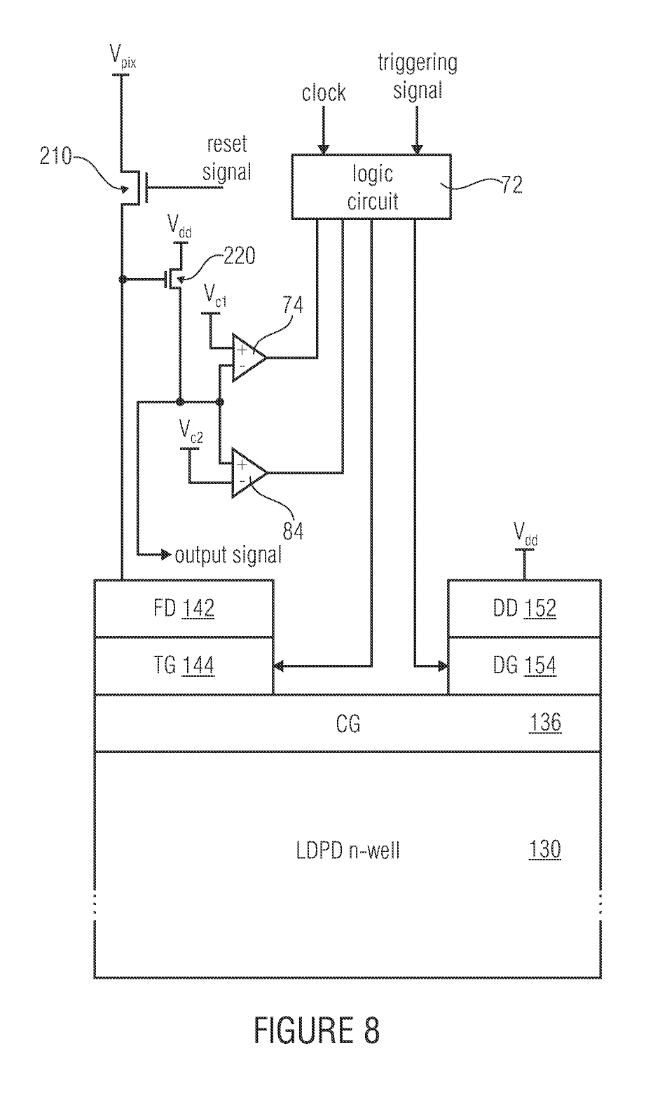

FIG. 8 shows a schematic circuit diagram of a pixel readout and control circuit of another embodiment, essentially corresponding to the pixel readout and control circuit shown in FIG. 7. In addition to the comparator 74, a further comparator 84 is provided comparing the current voltage at the detector terminal doping region to a second comparison value V_{c2} and providing a respective output signal to the logic circuit 82. The second comparison value V_{c2} can correspond, for example, to a lower threshold indicating that further discharge cycles are to be performed to obtain a meaningful measurement value for this pixel. The first comparison value V_{c1} can correspond to an upper threshold indicating that the detector terminal doping region of the pixel, when performing further discharge cycles, is in danger of becoming saturated. Hence, exceeding the first comparison value V_{c1} indicates that the transfer gate 144 of the respective pixel does not have to be opened until the end of the current measurement cycle, but that the photogenerated charges can be supplied directly to the charge draining doping region or the second detector terminal doping region 152. The second comparison value V_{c2} can, for example, be evaluated such that the same is evaluated across all pixels (or a representative partial selection of the pixels) as to whether the respective voltages at the detector terminal doping regions 142 are higher than the second comparison value V_{c2}. If this is the case for all pixels or the representative partial selection of the pixels, this means that the measurement cycle can be terminated.

As explained above, the PPD pixel approach not applying the disclosed technical teaching has several disadvantages. One of the problems is the occurrence of after-images resulting from the fact that a photodiode cannot be reset completely in the short time available due to the large allocated capacity within the photodiode and resetting by sub-threshold current on the one hand and the fact that the photogenerated charge carriers collected in the photodiode can only reach the floating diffusion by thermal diffusion due to the lack of an electrostatic potential gradient which would cause these charge carriers to drift in the direction of the floating diffusion. In the case of conventional photodiodes, this also eliminates the option of correct time and charge differentiation within several integration cycles.

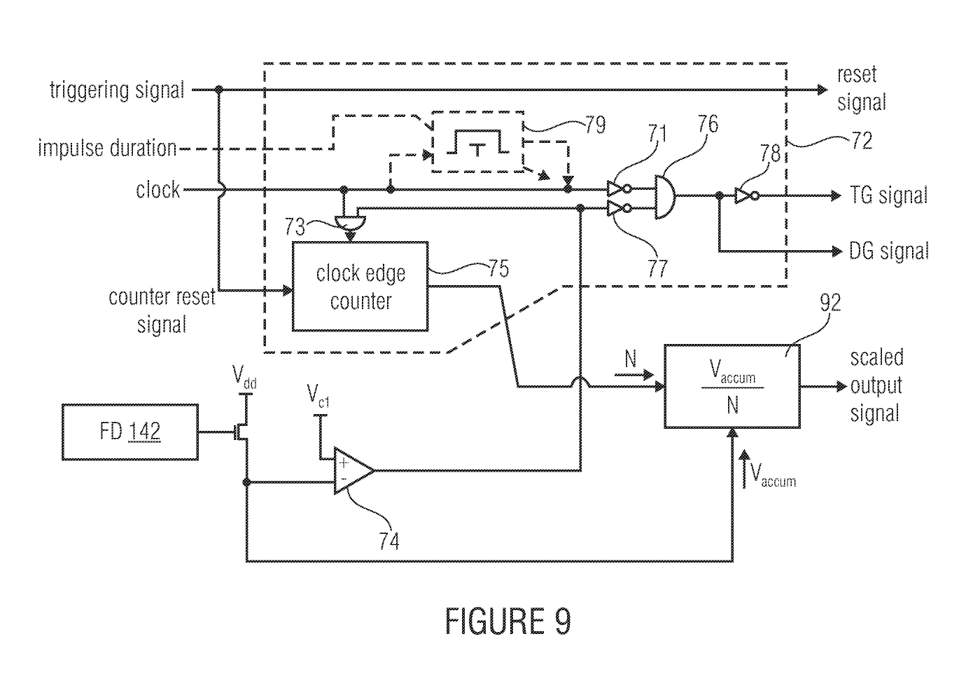

FIG. 9 schematically shows details of the pixel readout and control circuit. The logic circuit 72 comprises a clock edge counter 75 and several logic gates 71, 73, 76, 77 and 78. As is illustrated in FIG. 7, the logic circuit 72 comprises a triggering signal input, a clock signal input, a reset signal output, an output “TG SIGNAL” for the transfer gate 144 and an output “DG SIGNAL” for the draining gate or second transfer gate 154. Further, the logic circuit 72 comprises an input for a comparison signal generated by the comparator 74. Within the logic circuit 72, the clock signal is first supplied to an inverter 71 and then to an AND gate 76, where the same is ANDed with the inverted comparison signal. Inverting the comparison signal is performed by an inverter or a NOT gate 77. It should be noted that the function of combining the three logic circuits 71, 77 and 76 could also be implemented by an NOR gate. The AND gate 76 provides the control signal for the draining gate 154 at its output. By inverting the control signal for the draining gate 154 by means of a further inverter 78, the control signal is generated for the first transfer gate 154. In this way, the control signal for the first transfer gate 144 and the draining gate 154 are complementary to one another. However, it is also possible that the two control signals are in a different relation to one another. For example, it is possible that both control signals assume values at the same time, by which both the transfer gate 144 and the draining gate 154 are non-conductive. The comparison signal is generated by the comparator 74 and indicates whether a voltage V_{acuum} currently accumulated at the detector terminal doping region is higher than the comparison voltage V_{c1}. In a first operating state, the accumulated voltage V_{acuum} is smaller than the comparison voltage V_{c1}. Then, the comparator 74 provides a comparison signal having the value 0 or “low”. Accordingly, due to the inversion by the inverter 77, a signal having the value 1 or “high” is applied to the AND gate 76. In this way, the clock signal is gated to the output of the AND gate 76, i.e. the output of the AND gate 76 follows the clock signal. In a second operating state, the accumulated voltage V_{acuum} is higher than the comparison voltage V_{c1}, and the value 1 or “high” is applied to the output of the comparator. This can be interpreted such that no further charge accumulation is to be performed for the respective pixel in the second operating state. The inversion at the inverter 77 has the effect that one of the inputs at the AND gate 76 constantly receives the value 0 or “low”. Accordingly, the output of the AND gate 76 also constantly provides the value 0 or “low”. This has the effect that the transfer gate 144 remains non-conductive for the time being and hence no further transfer processes from the collection region to the detector terminal doping region 142 take place. The second transfer gate or draining gate 154 is, however, constantly open, so that charges can flow from the collection region into the second detector terminal doping region or charge draining doping region.

Since, in some embodiments, each pixel comprises an individual pixel control circuit, it can happen that different numbers of accumulation processes are performed for the pixels within a pixel array, depending on how strong the electromagnetic radiation incident on the respective pixel is. To take this into account, the clock edge counter 75 and a scaling circuit 92 can be provided. The clock edge counter 75 counts the clock edge of the clock signal while the comparison signal of the comparator 74 has the value 1 or “high”, which is obtained by the AND gate 73. Thereby, each clock edge corresponds to a specific number of discharge or laser impulse cycles (e.g. one clock edge corresponds to a discharge cycle). The clock edge counter is reset by the triggering signal, so that it starts counting from zero again in every measurement cycle. The number of counted clock cycles, during which the charge accumulation has been performed in the detector terminal doping region 142, is passed on to the scaling circuit 92. The scaling circuit 92 performs, for example, an analog division of the accumulated voltage V_{acuum} by the number N of clock cycles counted by the clock edge counter. In this way, a scaled output signal results at the output of the scaling circuit.

As an optional feature, FIG. 9 shows a timing element 79 receiving the clock signal at its input and outputting a modified clock signal at its output. The modified clock signal can, for example, be a square-wave signal, where the signal portions having the value 1 or “high” each have a defined period T. The timing element 79 can, for example, be a monostable circuit or a timer. If the timing element 79 exists, it replaces the parallel connection between the clock signal input and the AND gate 76. In the embodiment illustrated in FIG. 9, the impulse duration of the modified clock signal can be set via an impulse duration input of the logic circuit 72. The desired impulse duration can be transferred to the timing element 79, for example, in the form of an analog voltage or a digital value. In this way, a user can set the time duration, during which the charge carriers arriving at the collection region subsequent to a discharge or a laser impulse, are, at first, supplied to the charge draining doping region or the second detector terminal region 152. After the modified clock signal has again assumed the value 0 or “low”, the control signal for the transfer gate 144 assumes the value 1 or “high” due to the inverter 78, so that in the second clock phase the generated charge carriers can reach the first detector terminal doping region 142 from the collection region. Thus, the user has control over the differentiation or separation of the charge carriers to be evaluated and the charge carriers not to be evaluated or to be evaluated separately. When a charge carrier is in the collection region during the second clock phase, this charge carrier fulfils a condition as charge carrier to be evaluated.

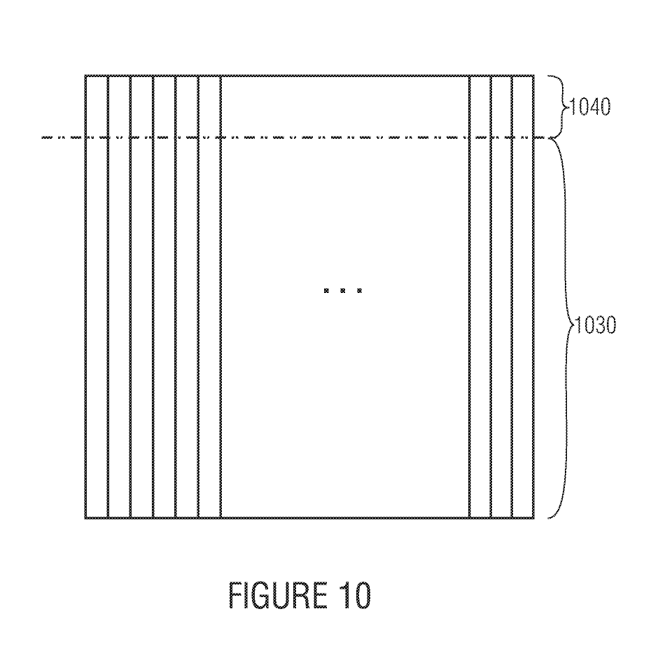

FIG. 10 shows a schematic top view of a pixel array which is implemented as a one-dimensional array of a plurality of row detectors. Each pixel comprises a detection region typically having a large extension in the longitudinal direction which can be between, for example, 100 μm and several millimeters. The detection regions of the plurality of pixels are indicated by reference number 1030 in FIG. 10. FIG. 10 also shows the control and readout regions 1040 of the pixels.

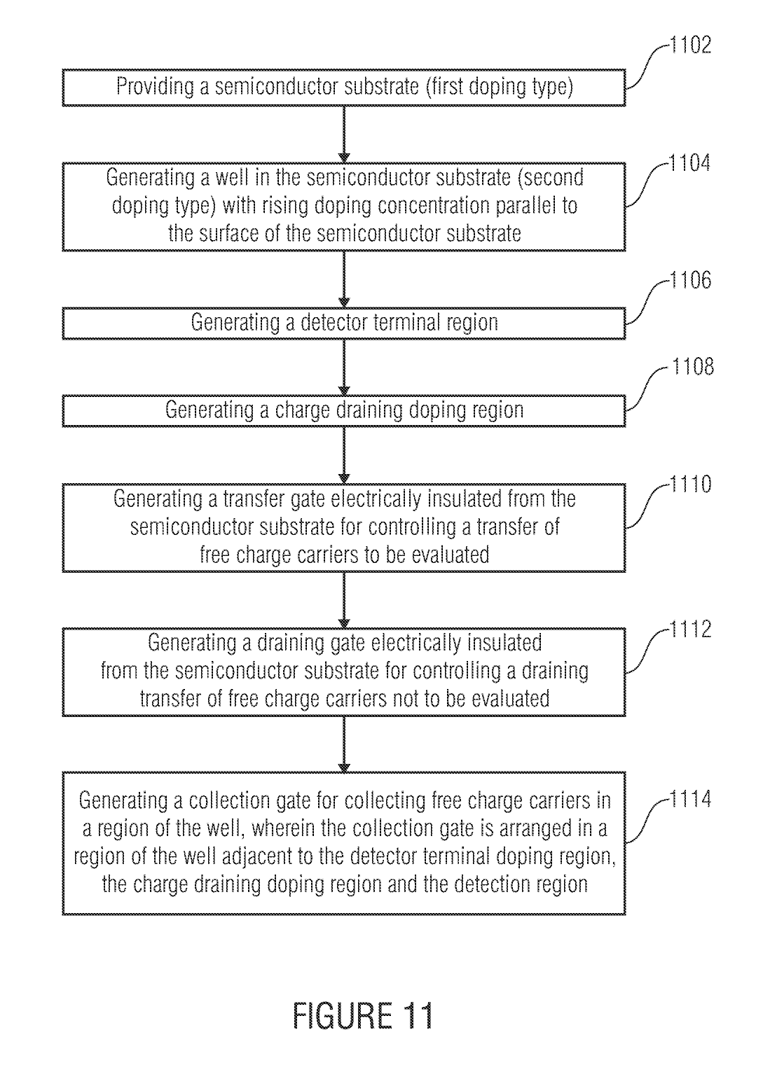

FIG. 11 shows a schematic flow diagram of a method for producing a detector. The method starts with providing 1102 a semiconductor substrate of a first doping type. This is followed by generating 1104 a well in the semiconductor substrate, wherein the well is of a second doping type different from the first doping type. In a direction parallel to a surface of the semiconductor substrate, the well comprises a rising dopant concentration. Then, a detector terminal region is generated, as is indicated by the box with reference number 1106. The detector terminal region is arranged at least partly in the well in a terminal region of the well, wherein the detector terminal doping region is of the same doping type as the well, wherein the well comprises a detection region comprising a maximum dopant concentration which is lower than a maximum dopant concentration of the terminal region of the well. This is followed by generating 1108 a second detector terminal doping region or charge draining doping region 152, which is arranged at least partly in the well. The charge draining doping region is of the same doping type as the well 130. Steps 1106 and 1108 can be performed simultaneously. At 1110, generating a transfer gate electrically insulated from the semiconductor substrate is performed for controlling a transfer of free charge carriers to be evaluated in a region of the well. The transfer gate is arranged in a region of the well between the detector terminal doping region and the detection region. A draining electrode or second transfer gate electrically insulated from the semiconductor substrate for controlling a draining transfer from free charge carriers not to be evaluated is generated in a region of the well, as is indicated at 1112. The draining gate is arranged in a region of the well between the charge draining doping region and the detection region. During generating 1114 a collection electrode for collecting free charge carriers in a region of the well, the collection electrode is arranged in a region of the well adjacent to the detector terminal doping region, the charge draining doping region (i.e. the second detector terminal doping region) and the detection region.

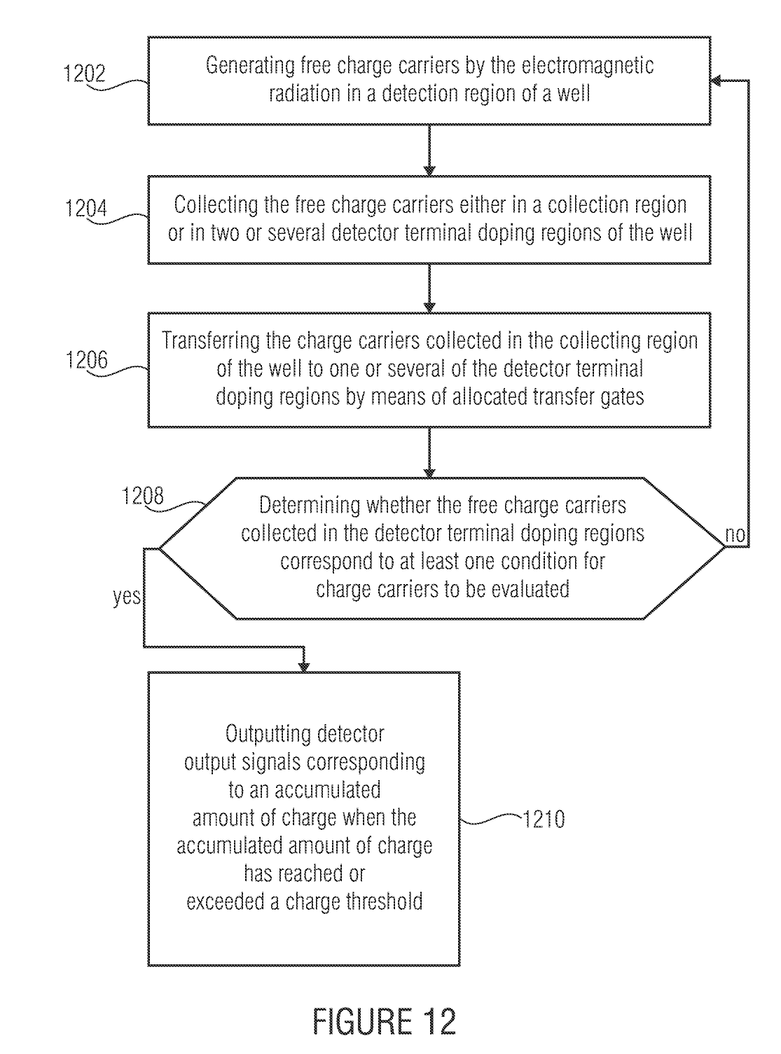

FIG. 12 shows a schematic flow diagram of a method for detecting electromagnetic radiation. First, free charge carriers are generated by the electromagnetic radiation in a detection region of a well, as is shown at a step having reference number 1202. The well is arranged in a semiconductor substrate, wherein the semiconductor substrate is of a first doping type and the well of a second doping type. The first doping type and the second doping type are different, and the well comprises a rising dopant concentration in a direction parallel to the surface of the semiconductor substrate. Subsequently, or also simultaneously, collecting 1204 the free charge carriers in a collection region of the well takes place, which is arranged at least partly in the well in a terminal region of the well. Then, the collected charge carriers are transferred into a detector terminal doping region dedicated for this by means of the respective transfer gate. then a branching point 1206 follows, where it is determined whether the free charge carriers collected in the detector terminal doping region correspond to at least one condition for charge carriers to be evaluated. If the collected free charge carriers correspond to the at least one condition, the same will be evaluated. Otherwise, when the collected free charge carriers do not correspond to at least one condition for charge carriers to be evaluated, the cycle of collecting the photogenerated charge carriers, their transfer and the evaluation is repeated.

In the past, there have been different approaches for solving this problem, most of which avoided giving up the advantages of the pinned diode approach. One example is U.S. Pat. No. 5,903,021 by Lee et al. of 1995. In their approach, the pixel comprises a photodiode with a pinned region, a non-pinned region and means for resetting the diode. These features can also be found in an detector according to the technical teaching disclosed herein. Since a significant part of the photosensitive region has a pinned surface potential, the pixel of the detector disclosed herein maintains the advantages of the PPD pixel in this regard. The difference to the LDPD approach used herein is that in the U.S. Pat. No. 5,903,021 the transfer gate and the detector terminal doping regions are completely eliminated for increasing the filling factor of the pixel. With this, in the apparatus according to U.S. Pat. No. 5,903,021, the advantages of separate photoactive regions and readout regions, of an adjustable charge-to-voltage conversion factor, of enabling non-destructive readout and the option of performing “real” correlated double sampling in rolling shutter integration operation are also eliminated. Based on this idea of using a PPD without any means for charge coupling, which could allow a separation into photoactive region and a pixel-integrated readout region (for which the transfer gate would be necessitated that had previously been eliminated within the disclosure of U.S. Pat. No. 5,903,021), Lee et al. correctly state that for providing fast reset velocities it is also necessitated to ensure fast transition of all photo electrodes present in the pinned region of the photodiode to the non-pinned region. For that purpose, U.S. Pat. No. 5,903,021 suggests building up an electric field forcing these electrodes into the non-pinned region by tapering the existing n photodiode implantation, p-doped pinning layer implantation or any other additional n- or p-doped implantations in order to effect a two-dimensional modulation of the electrostatic potential.

In the case of the LDPD device, the pinned region is based on a photodiode well, similar to the suggestion by Lee et al., additionally comprising a non-uniform lateral doping profile. On the other hand, the non-pinned region of the same photodiode well is used to produce two additional buried channel gates (as in the buried charge coupled devices (CCD), but with the option of non-destructive readout), which are used for modulating the electrostatic potential within the non-pinned part of the photodetector. The collection gate 136 is used for generating an additional electrostatic potential maximum within the photodetector well, which serves as a charge collection point (and can control the overall well capacity and the charge carrier transfer velocity within the photodiode by means of external bias potentials). According to the technical teaching disclosed herein, the transfer gate 144 and the draining gate 154 are both used for allowing the fast transfer of photogenerated charge carriers collected below the collection gate 136 and/or the transfer gate 144 into one (or several) floating diffusions or detector terminal doping region(s) 142 during the reset and readout operating modes, or for preventing this transfer by generating a potential barrier for the charge carriers collected in this region during the charge collection operating mode. This approach allows an external influence on the height of the barrier and allows at the same time an almost noise-free and fast (with transit times of merely several microseconds for detection ranges having lengths L >200 μm) charge transfer through the non-pinned region when the potential maxima below the gates are pushed away from the silicon surface due to the approach of a CCD having a buried channel. The characteristics of a separation of photoactive region and readout region as well as a charge coupling approach can (also) be found in the disclosed technical teaching.

In U.S. Pat. No. 7,391,066 B2 and in the US patent application disclosure No. 2004/0253761 A1, Rhodes et al. state correctly that the heavily doped n⁺ regions, as they exist in the detector disclosed herein, for example in the detector terminal doping region 142, apart from providing good charge transfer characteristics and a good ohmic contact to metallic conductors, generate a charge leakage in the PPD pixel in the direction of the substrate type region. Such a charge leakage reduces the collected light signal transmitted to the gate of the source follower transistor 220. According to the findings of Rhodes et al., the transfer gate (which still exists in the LDPD approach) is eliminated, and the ohmic contact to the photodiode well is established by means of a more weakly doped diffusion (n⁻), wherein the photodiode well serves, at the same time, as source electrode of the reset transistor. According to Rhodes et al., in this way, a floating diffusion (n⁻ contact to the photodiode well) is provided, which is not subject to charge leakage. In the LDPD pixel, this separation of detector terminal doping region 142 and photoactive region is provided by introducing an externally controlled barrier between the same in the form of the transfer gate 144.

In U.S. Pat. No. 5,705,836, Agwani et al. address the same charge transfer and after-image problems as the technical teaching disclosed herein, however in their case with CCD cameras. They state that they have provided a fast and efficient charge transfer structure for usage in charge coupled device arrays (CCD arrays) having a large pixel pitch. In their approach, the channel structures below the CCD gates include a plurality of area structures, wherein each area structure is characterized by a uniform potential which differs from the potential characterizing each of the other area structures, i.e. the introduction of a non-uniform lateral doping profile below the CCD structures. Apart from the fact that this idea is completely based on CCD arrays and that the LDPD pixel configuration has been developed for CMOS photo arrays, the fact that the non-uniform lateral doping is covered by polysilicon gates (as is the case in CCD devices) reduces its photosensitivity in the ultraviolet, blue and green regions of the spectrum. Apart from that, an LDPD pixel necessitates a significantly simpler control signal system than an average CCD array.

Another approach indicating how to solve this problem has been suggested by Jan Lohstroh in the U.S. Pat. No. 4,245,233 of 1981. In this patent, it is suggested to use a photo control electrode or photo gate having a high resistance as a photodetector and to apply a potential difference at its edges parallel to the photoactive area for generating a drift field within the depletion layer caused in the channel region below the photo gate which extends transversely across the photosensitive area, essentially in parallel to the main surface of the photo gate and in the direction of an edge portion of the photo gate, so that the photogenerated charge carriers are transported on the whole photoactive area along said drift field to the stated edge portion, where they finally reach the readout node (floating diffusion FD). Apart from the reduced photosensitivity in the ultraviolet and blue regions of the spectrum, which is characteristic for all photo gate approaches, one of the main disadvantages of this approach is the current flowing through the photo gate due to its high resistance and the potential difference generated transversely across the same. This current causes high power consumption of the suggested device and limits the number of pixels that can be produced functionally in a photosensitive pixel array. The LDPD pixel suggested herein does not have these types of power consumption and heat generation problems.

In addition, starting from the technical teaching presented herein, the usually existing overall well capacity problems of photo gates, CCD and PPD pixel structures can be solved at least partly by an appropriate design of the collection gate 136, the detector terminal doping region 142 and their appropriate provision with an electric potential, when the photodetector has been produced, since the charge is actually collected below the collection gate and is finally read out through the detector terminal doping region 142.

In this device, the signal-to-noise ratio can be improved further by using specific readout techniques, such as averaging by multiple readout for charge accumulation, specific correlated double samplings (CDS) or pixel-internal signal processing.

All the statements made above point in the direction of an ultra low noise CMOS-compatible photodetector solution having high response velocity, a large photoactive area and high versatility which could be the future for modern spectroscopy, since the same is more cost-effective than the common photoelectron multiplier approach.

The already stated advantages of a CMOS row detector with induced lateral drift fields due to respective measures during well production can be summarized as follows:
Efficiency of a lateral electrostatic potential gradient induced by a dopant concentration gradient within the photodetector has the effect that the drift mechanisms dominate the diffusion mechanisms during the charge transfer and readout phases, i.e. the response velocity of the photodetector is significantly increased in this way compared to conventional solutions. This allow a feature of time discrimination used for charge discrimination, wherein the “desired” charge can be separated from the charge that is “undesired” or to be evaluated separately within an appropriate time interval which is similar to the effect of a photoelectron multiplier.
The presence of the grounded, highly doped layer (of the same type as the silicon substrate on which the photodetector is produced) on the diffused, flat well “forces” the electrostatic potential maximum away from the silicon surface (FIG. 3a) and amplifies recombination mechanisms at the silicon surface. These two effects reduce the surface-generated dark current component of the photodetector and the amount of equivalent noise charge (ENC), which provides a much better signal-to-noise ratio compared to conventional solutions. This result is essential for integration times that can vary between several hundred microseconds to several seconds and allows this solution to be used in spectrography applications.
The fact that the readout nodes, here the detector terminal doping region(s) or the floating diffusion(s), can be separated from the photoactive area by the transfer gate(s), allows non-destructive readout, which means signal monitoring over time and the option of charge collection without resetting the detector terminal doping region(s) across several radiation periods.
The overall well capacity or the maximum possible amount of collected charge depends on the collection gate and the detector terminal doping region(s), their suitable design for optimizing this characteristic and their external potential provision (“bias”) and no longer from the flat well characteristics, which is the problem normally existing in the conventional solutions. In the technical teaching disclosed herein, this represents a significant feature due to the necessity of collecting charge across long time periods across several integration cycles.
The dynamic range and the signal-to-noise ratio can be improved by multiple charge transfer accumulation without adding additional readout noise to the pixel output signal, opening up options of using the CMOS APS (complementary metal oxide semiconductor active pixel sensor) for spectrography and other similar applications.

While some aspects have been described in the context of a device, it is obvious that these aspects also represent a description of the respective method, so that a block or a member of a device can also be considered as a respective method step or as feature of a method step. Analogously, aspects having been described in the context of a method step or as a method step also represent a description of a respective block or a detail or feature of a respective device. Some or all of the method steps can be performed by a hardware device (or by using a hardware device), such as a microprocessor, a programmable computer or an electronic circuit. In some embodiments, some or several of the most important method steps can be executed by such a device.

In particular, it should be noted that, depending on the circumstances, the inventive scheme can also be implemented in software. The implementation can be made on a digital memory medium, in particular a disc, a CD or a DVD or the like having electronically readable control signals that can cooperate with a programmable computer system such that the respective method is performed. Generally, the invention also consists of a computer program product with a program code for performing the method stored on a machine-readable carrier when the computer program product runs on a computer. In other words, the invention can be realized as a computer program having a program code for performing at least one of the methods when the computer program product runs on a computer.

While this invention has been described in terms of several advantageous embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A detector for detecting electromagnetic radiation, comprising:
a semiconductor substrate of a first doping type;
a well in the semiconductor substrate, wherein the well is of a second doping type, wherein the first doping type and the second doping type are different, and wherein the well comprises a rising dopant concentration in a direction parallel to a surface of the semiconductor substrate;
two or more detector terminal doping regions arranged at least partly in the well in a terminal region of the well, wherein the detector terminal doping regions are of the same doping type as the well, wherein the detection of the electromagnetic radiation is based on a generation of free charge carriers by the electromagnetic radiation in a detection region of the well comprising a maximum dopant concentration that is lower than a maximum dopant concentration of the terminal region of the well;
two or more transfer gates electrically insulated from the semiconductor substrate for controlling a transfer of free charge carriers to be evaluated in a region of the well, wherein the transfer gates are each arranged in a region of the well between one of the detector terminal doping regions and the detection region; and
a collection gate for collecting free charge carriers in a region of the well, wherein the collection gate is electrically insulated from the semiconductor substrate and is arranged in a region of the well adjacent to the detector terminal doping regions, the transfer gates and the detection region.

2. The detector according to claim 1, wherein the detector terminal doping regions are arranged adjacent to each other on one side of the well.

3. The detector according to claim 1 comprising, as a further feature, an insulation region between at least two of the detector terminal doping regions.

4. The detector according to claim 1 comprising, as a further feature, an electrode control for controlling at least one of the transfer gates.

5. The detector according to claim 4, wherein the electrode control is implemented to control the transfer gates such that the transfer of the free charge carriers to be evaluated that develop during a first phase in the detection region is made to a first detector terminal doping region of the two or more detector terminal doping regions, and the transfer of the free charge carriers to be evaluated that develop during a second phase in the detection region is made to a second detector terminal doping region of the two or more detector terminal doping regions at different times.

6. The detector according to claim 4, wherein the electrode control comprises a timing element which is implemented to indicate, subsequent to an event, an expiry of a specific time period by means of a timing element output signal, wherein the presence of a condition to be fulfilled by the charge carriers to be evaluated results from the timing element output signal.

7. The detector according to claim 1 comprising, as a further feature, a reset circuit for resetting the detector terminal doping regions,
wherein the detector is implemented to perform a plurality of transfer processes of the free charge carriers to be evaluated between two reset processes, in order to integrate an amount of charge of the free charge carriers to be evaluated across the plurality of transfer processes.

8. The detector according to claim 7 comprising, as a further feature, an amount of charge measurement and a comparator, which are implemented to compare a measured amount of charge in one of the detector terminal regions with a threshold for the measured amount of charge to determine whether at least one further transfer process is to be performed by means of the transfer gate which is allocated to the detector terminal region.

9. The detector according to claim 1, wherein one or several detector terminal doping regions are connected to a potential source for providing an electric potential, which is implemented to serve as a drain for the free charge carriers.

10. The detector according claim 1 comprising, as a further feature, at least one counter for a number of transfer processes since a last reset of the detector terminal doping region.

11. The detector according to claim 10 comprising, as a further feature, a scaling circuit for scaling a detector output signal based on the number of transfer processes.

12. A method for producing a detector, comprising:
providing a semiconductor substrate of a first doping type;
generating a well in the semiconductor substrate, wherein the well is of a second doping type different to the first doping type, and wherein the well comprises a rising dopant concentration in a direction parallel to a surface of the semiconductor substrate;
generating at least two detector terminal doping regions arranged at least partly in the well in a terminal region of the well, wherein the detector terminal doping regions are of the same doping type as the well, wherein the well comprises a detection region comprising a maximum dopant concentration which is lower than a maximum dopant concentration of the terminal region of the well;
generating at least two transfer gates electrically insulated from the semiconductor substrate for controlling a transfer of free charge carriers to be evaluated in a region of the well, wherein the transfer gates are each arranged in a region of the well between the at least two detector terminal doping regions and the detection region; and
generating a collection gate for collecting free charge carriers in a region of the well and for generating a constant electrostatic potential effecting an even distribution of the charge carriers collected below the collection electrode between several detector terminal doping regions, each via a transfer gate, wherein the collection gate is arranged in a region of the well adjacent to the detector terminal doping regions, the transfer gates and the detection region.

13. A method for detecting electromagnetic radiation, comprising:
generating free charge carriers by the electromagnetic radiation in a detection region of a well, wherein the well is arranged in a semiconductor substrate, wherein the semiconductor substrate is of a first doping type and the well of a second doping type, wherein the first doping type and the second doping type are different, and wherein the well comprises a rising dopant concentration in a direction parallel to the surface of the semiconductor substrate;
collecting the free charge carriers in a collection region of the well arranged at least partly in the well in a terminal region of the well, or in two or more detector terminal doping regions connected to the collection region of the above-stated well by means of the allocated transfer gates;
transferring the charge carriers collected in the collection region of the well to one or several detector terminal doping regions by means of the associated transfer gates;
determining whether the free charge carriers collected in the detector terminal doping regions correspond to at least one condition for charge carriers to be evaluated;
depending on whether the free charge carriers collected in the detector terminal doping regions correspond to the at least one condition:
a) repeating generating, collecting and transferring the charge carriers as described above, or
b) outputting detector output signals corresponding to an accumulated amount of charge in one of the detector terminal regions when the accumulated amount of charge has reached or exceeded a charge threshold.

14. The method according to claim 13, further comprising:
resetting at least one of the two or more detector terminal doping regions by temporarily connecting the detector terminal doping region with a potential source providing an electrical potential serving as a drain for the transferred free charge carriers;
determining whether an amount of charge accumulated since resetting in the detector terminal doping regions has reached or exceeded a charge threshold.

15. The method according claim 13, further comprising:
counting a number of cycles of transferring the free charge carriers collected and to be evaluated from the collection region to one of the detector terminal regions; and
scaling a detector output signal of the stated detector terminal doping regions as a function of the number of cycles.

16. The method according to claim 13, wherein the electromagnetic radiation varies over time according to a time curve and the method further comprises:
transferring the charge carriers generated in the detection region to different detector terminal doping regions by means of a selection of the transfer gates allocated to the different detector terminal regions in a time-variable manner synchronously to the time curve of the electromagnetic radiation;
evaluating the amounts of charge collected in the different detector terminal doping regions and outputting the detector output signals corresponding to the collected amounts of charge.
